(19) United States
(12) Patent Application Publication
(10) Pub. No.: US 2012/0279342 A1
(43) Pub. Date: Nov. 8, 2012

(54) MOTOR, ROBOT HAND, AND ROBOT

(75) Inventors: Shinji YASUKAWA, Shiojiri (JP); Osamu MIYAZAWA, Shimosuwa (JP)

(73) Assignee: SEIKO EPSON CORPORATION, Tokyo (JP)

(21) Appl. No.: 13/461,216

(22) Filed: May 1, 2012

(30) Foreign Application Priority Data
May 2, 2011 (JP) 2011-102756

(51) Int. Cl. B25J 18/00; B25J 15/00; H01L 41/08

(52) U.S. Cl. 74/490.03; 310/328; 294/213; 901/38; 901/23

(57) ABSTRACT

A motor including a driven unit; an actuator including a vibrating plate having, at an end thereof, a protrusion which is biased toward the driven unit and a piezoelectric body stacked on the vibrating plate; and a biasing unit biasing the actuator toward the driven unit, wherein an axis in a direction in which the biasing unit biases the actuator toward the driven unit intersects with a plane containing a vibrating surface of the vibrating plate.

### BACKGROUND

1. Technical Field

The present invention relates to motors, robot hands, and robots.

2. Related Art

As a motor driving a driven body by the vibration of a piezoelectric element, a motor that drives a driven body by making a protrusion of a reinforcing plate come into contact with the driven body in an actuator formed of the reinforcing plate having the protrusion integrally formed therein, the reinforcing plate on which a rectangular flat plate-like piezoelectric element is stacked, is known (JP-A-2010-233335 (Patent Document 1)). The motor provided with a piezoelectric actuator includes a biasing unit for making the protrusion of the reinforcing plate of the piezoelectric actuator come into contact with the driven body, and a frictional force developed between the protrusion of the reinforcing plate and the driven unit by a biasing force generated by the biasing unit transfers the vibration of the protrusion of the reinforcing plate to the driven unit and drives the driven unit in a predetermined direction.

However, in Patent Document 1 described above, the direction in which the piezoelectric actuator is biased by the biasing unit toward the driven body is biased along a vibrating surface of planar vibration in the reinforcing plate toward the driving center of the driven body. In such a motor, depending on the deflection of the driven body rotatably secured to an apparatus main body and the amount of backlash of the piezoelectric actuator slidably secured to the apparatus main body, a relative slippage (slip) occurs in a region of contact between the driven body and the protrusion of the piezoelectric actuator in a direction intersecting with the biasing direction. This slippage (slip) greatly reduces the efficiency of transfer of the vibration of the piezoelectric actuator to the driven body.

### SUMMARY

An advantage of some aspects of the invention is to provide a motor that prevents a slip between an actuator and a driven body in a region of contact between the driven body and a protrusion of a piezoelectric actuator, the slip caused by a relative slippage in a direction intersecting with a biasing direction, and transfers the vibration of the piezoelectric actuator to the driven body efficiently and a robot hand and a robot that use such a motor.

### Application Example 1

This application example is directed to a motor including: a driven unit; an actuator including a vibrating plate having, at an end thereof, a protrusion which is biased toward the driven unit and a piezoelectric body stacked on the vibrating plate; and a biasing unit biasing the actuator toward the driven unit, wherein a direction in which the biasing unit biases the actuator toward the driven unit intersects with a vibrating surface of the vibrating plate.

According to the application example described above, by disposing the biasing unit biasing the actuator toward the driven unit in such a way that the biasing unit biases the actuator toward the driven unit in a direction intersecting with the vibrating surface of the vibrating plate which is excited by the piezoelectric body included in the actuator, a biasing force biasing the actuator toward the driven unit along the vibrating surface of the vibrating plate and a biasing force biasing the actuator in the direction intersecting with the vibrating surface of the vibrating plate are applied to the actuator. Of these biasing forces, by the biasing force biasing the actuator in the direction intersecting with the vibrating surface of the vibrating plate, the driven unit which makes contact with the actuator is also biased in the direction intersecting with the vibrating surface of the vibrating plate of the actuator. As a result, deflection and backlash due to a clearance between the parts in a driving portion provided to make it possible to drive the driven unit and deflection and backlash due to a clearance between the parts in a sliding portion provided to allow the actuator to slide on a motor base are moved to one side in a predetermined direction by the biasing force biasing the actuator in the direction intersecting with the vibrating surface of the vibrating plate, making it possible to prevent deflection and backlash when the driven unit is driven. This makes it possible to prevent a transfer loss of the vibration of the actuator and obtain a motor that can drive the driven unit efficiently.

### Application Example 2

This application example is directed to the motor of the application example described above, wherein an angle θ at which the direction in which the biasing unit biases the actuator toward the driven unit intersects with the vibrating surface may satisfy 0<θ≦30°.

According to the application example described above, it is possible to obtain an efficient motor with a small transfer loss of the vibration of the actuator, the motor in which a transfer loss of vibration due to frictional resistance in a portion in which the actuator slides on the motor base is reduced, deflection and backlash in the actuator and the driven unit are moved to one side in a predetermined direction by the biasing force biasing the actuator in the direction intersecting with the vibrating surface of the vibrating plate, and deflection and backlash are prevented when the driven unit is driven.

### Application Example 3

This application example is directed to the motor of the application example described above, wherein a regulating unit regulating the actuator in a direction intersecting with the vibrating surface may be provided.

According to the application example described above, it is possible to prevent the actuator from being excessively moved to one side in a predetermined direction by the biasing force biasing the actuator in the direction intersecting with the vibrating surface of the vibrating plate. This makes it possible to ensure contact between the driven unit and the actuator.

### Application Example 4

This application example is directed to a robot hand including the motor of the application example described above.

The robot hand of this application example can be made compact and lightweight while having a high degree of flexibility and a large number of motors.

### Application Example 5

This application example is directed to a robot including the robot hand of the application example described above.

The robot of this application example is highly versatile and can perform assembly, inspections, etc. of a sophisticated electronic apparatus.

### BRIEF DESCRIPTION OF THE DRAWINGS

The invention will be described with reference to the accompanying drawings, wherein like numbers reference like elements.

FIG. 1 is an exploded perspective view showing a motor according to a first embodiment.

FIGS. 2A and 2B show the motor according to the first embodiment, Fig. A being an assembly plan view and FIG. 2B being an assembly side view.

FIGS. 3A to 3C are sectional views taken on the line A-A′ shown in FIG. 2A.

FIGS. 4A and 4B are plan views illustrating the operation of an actuator according to the first embodiment.

FIGS. 5A and 5B are schematic diagrams illustrating the operation of a biasing unit according to the first embodiment.

FIG. 6 is an appearance diagram showing a robot hand according to a second embodiment.

FIG. 7 is an appearance diagram showing a robot according to a third embodiment.

### DESCRIPTION OF EXEMPLARY EMBODIMENTS

Hereinafter, embodiments according to the invention will be described with reference to the drawings.

### First Embodiment

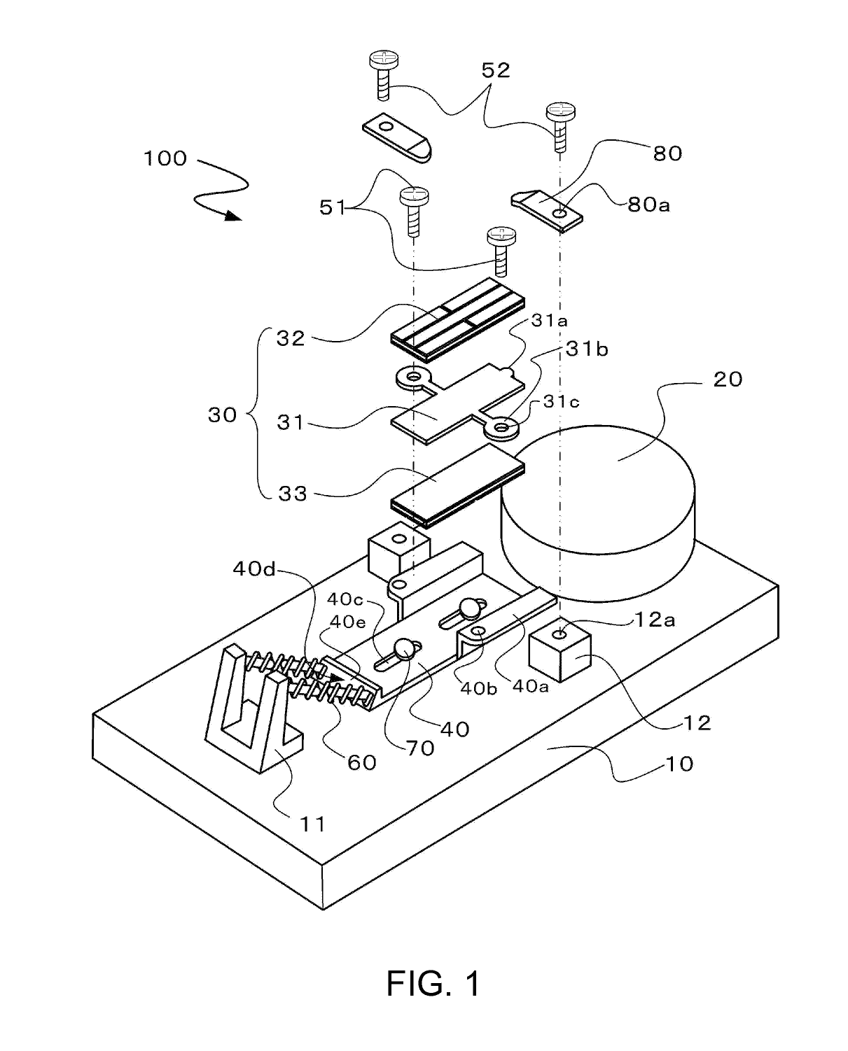

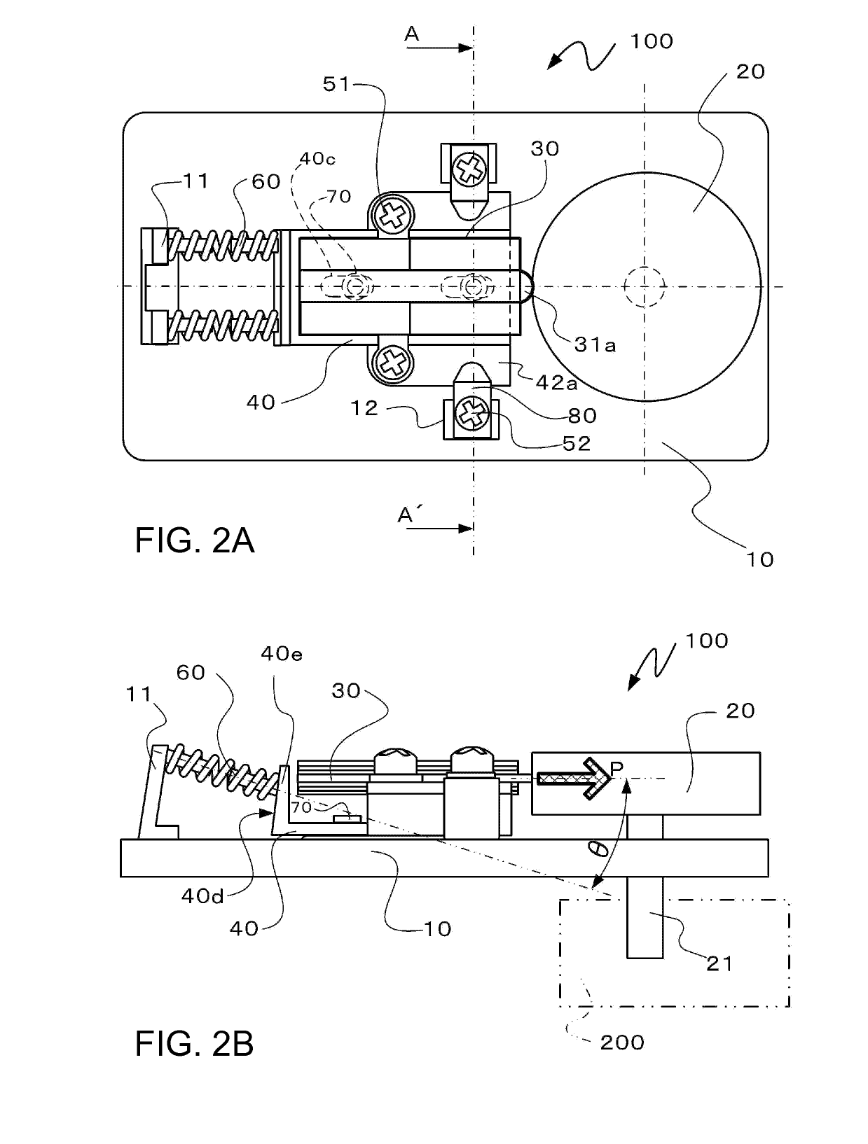

FIG. 1 and FIGS. 2A and 2B show a motor 100 according to an embodiment, FIG. 1 being an exploded perspective view, FIG. 2A being an assembly plan view, and FIG. 2B being an assembly side view. As shown in FIG. 1 and FIGS. 2A and 2B, the motor 100 includes a driven body 20 rotatably secured to a base 10, a support 40 slidably secured to the base 10, a coil spring 60 as a biasing unit that biases the support 40 toward the driven body 20, and an actuator 30 that is secured to the support 40 to be biased and drives the driven body 20 by vibration.

Moreover, the actuator 30 is formed of piezoelectric elements 32 and 33, each being a rectangular piezoelectric body in which an electrode is formed, and a vibrating plate 31, the piezoelectric elements 32 and 33 bonded together in such a way as to sandwich the vibrating plate 31. Examples of the piezoelectric elements 32 and 33 are piezoelectric materials such as lead zirconate titanate (PZT:Pb(Zr,Ti)O₃), crystal, and lithium niobate (LiNbO₃); in particular, PZT is suitably used. Furthermore, the electrode to be formed can be formed by forming a film of conductive metal such as Au, Ti, or Ag by vapor deposition, sputtering, or the like. As the actuator 30, the vibrating plate 31 has, at an end thereof, a projection 31a that is secured to the support 40, biased by the coil spring 60 toward the driven body 20, and brought into contact with the driven body 20. Incidentally, the vibrating plate 31 is formed of stainless steel, nickel, rubber metal, or the like, and stainless steel is suitably used because the stainless steel can be processed easily. The actuator 30 is secured to the support 40 with screws 51 that are placed through holes 31c of mounting sections 31b formed in the vibrating plate 31 for mounting on the support 40 and are fitted into screw holes 40b of fixing sections 40a formed in the support 40.

The support 40 is slidably secured to the base 10 as a result of securing a fixing pin 70 placed through a guide hole 40c of the support 40 to the base 10. At an end of the support 40 opposite to the driven body 20, a spring mounting section 40e having a biased surface 40d on which the coil spring 60 as the biasing unit is placed, the biased surface 40d biased by the coil spring 60, is provided. The coil spring 60 placed in the spring mounting section 40e is held, at one end thereof, by a spring holding section 11 of the base 10, and biases the spring mounting section 40e, that is, the support 40 toward the driven body 20 by the deflection of the coil spring 60.

As shown in FIG. 2B, the coil spring 60 as the biasing unit is held between the spring holding section 11 and the spring mounting section 40e at an angle θ with respect to the direction of an arrow P which is a direction in which the support 40 is biased, that is, the actuator 30 is biased toward the driven body 20, in such a way as to generate also a force in a direction in which the spring mounting section 40e of the support 40 is pressed against the base 10. It is preferable that the angle θ be 0°<θ≦30° so as not to increase the frictional force in a region of contact between the support 40 and the base 10.

Moreover, the base 10 has spring supporting sections 12 to which leaf springs 80 as a regulating unit for the support 40, which will be described later, are secured, and the leaf springs 80 are secured to the spring supporting sections 12 with screws 52 that are placed through holes 80a of the leaf springs 80 and are fitted into screw holes 12a of the spring supporting sections 12.

The driven body 20 is rotatably secured to the base as a result of attaching a rotating shaft 21 to an unillustrated bearing of the base 10. The driving (rotation) of the driven body 20 is adjusted to a desired rotation speed or to produce desired output torque via a reduction or speed increasing gear 200 connected to the rotating shaft 21 to drive a driven apparatus.

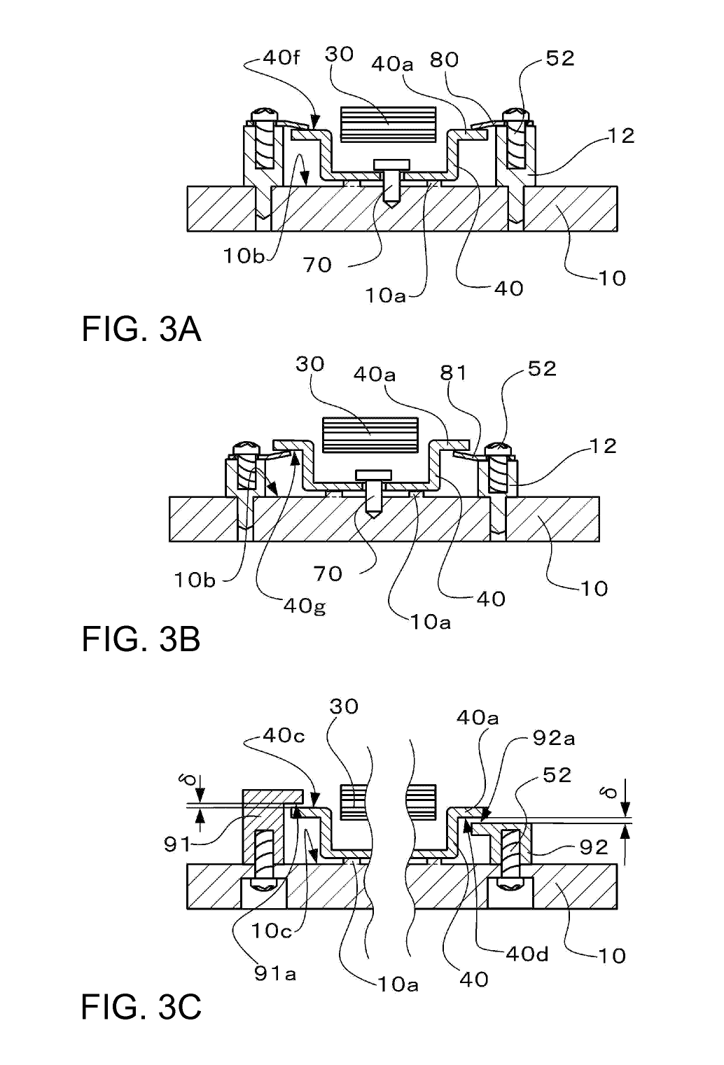

A section taken on the line A-A′ shown in FIG. 2A is shown in FIG. 3A. As shown in FIG. 3A, the leaf springs 80 are secured to the spring supporting sections 12 with the screws 52, the spring supporting sections 12 secured to the base 10. In this embodiment, the tips of the leaf springs 80 are fixed in such a way that the tips are close to top sides 40f (hereinafter referred to as front sides 40f), which are shown in the drawing, of the fixing sections 40a, and the movement of the support 40 in a direction in which the support 40 moves away from the base 10 is regulated.

The base 10 has, on a side 10b thereof where the actuator 30 is mounted, a rail 10a formed as a protrusion for reducing the range of contact between the base 10 and the support 40 to allow the support 40 to slide on the base 10 more smoothly. In this embodiment, as the rail 10a, two rails 10a are formed in the direction in which the coil spring 60 biases the support 40, but the invention is not limited thereto. There may be one rail 10a or three or more rails 10a. Since the rail 10a formed in this manner may allow the support 40 to move toward the base 10, the support 40 can also be mounted in such a way that the tips of springs 81 are close to sides 40g (hereinafter referred to as back sides 40g) opposite to the front sides 40f as shown in FIG. 3B.

Moreover, as shown in FIG. 3C, it is possible to regulate the movement of the support 40 by leaving a predetermined clearance δ between a regulating surface 91a and the front side 40f and between a regulating surface 92a and the back side 40g by using regulating blocks 91 and 92 without using the leaf springs 80 and 81. In such a case, it is preferable that δ be set at 0.01 to 0.02 mm. If δ is less than 0.01 mm, a collision between the regulating surface 91a and the front side 40f or between the regulating surface 92a and the back side 40g increases in number, making it difficult for the support 40 to slide on the base 10 smoothly; if δ exceeds 0.02 mm, an up-and-down movement of the support 40 in the drawing becomes large, which impairs driving efficiency.

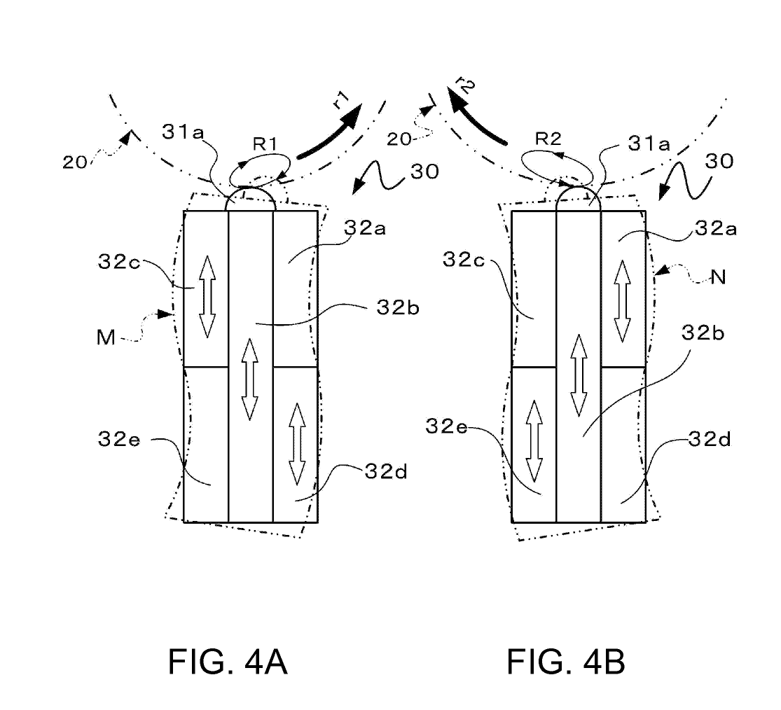

Next, the operation of the actuator 30 will be described by using FIGS. 4A and 4B. FIGS. 4A and 4B are schematic plan views showing vibration movements of the actuator 30. As shown in FIG. 4A, by the application of an alternating-current voltage between electrodes 32c, 32b, and 32d of electrodes 32a, 32b, 32c, 32d, and 32e formed in the piezoelectric element 32 and electrodes formed on the side opposite to the electrodes 32c, 32b, and 32d with an unillustrated piezoelectric body sandwiched between them, longitudinal vibration of the piezoelectric body in regions in which the electrodes 32c, 32b, and 32d are formed, the longitudinal vibration in the direction of arrows shown in the drawing, is excited. In the region corresponding to the electrode 32b, the actuator 30 is longitudinally vibrated in the direction of the arrow shown in the drawing, and, in the regions corresponding to the electrodes 32c and 32d, flexing vibration of the actuator 30, the flexing vibration indicated with a shape M, is excited. As a result, the projection 31a of the vibrating plate 31 vibrates in an elliptic orbit R1.

Moreover, as shown in FIG. 4B, by the application of an alternating-current voltage between the electrodes 32a, 32b, and 32e of the electrodes 32a, 32b, 32c, 32d, and 32e formed in the piezoelectric element 32 and electrodes formed on the side opposite to the electrodes 32a, 32b, and 32e with an unillustrated piezoelectric body sandwiched between them, longitudinal vibration of the piezoelectric body in regions in which the electrodes 32a, 32b, and 32e are formed, the longitudinal vibration in the direction of arrows shown in the drawing, is excited. In the region corresponding to the electrode 32b, the actuator 30 is longitudinally vibrated in the direction of the arrow shown in the drawing, and, in the regions corresponding to the electrodes 32a and 32e, flexing vibration of the actuator 30, the flexing vibration indicated with a shape N, is excited. As a result, the projection 31a of the vibrating plate 31 vibrates in an elliptic orbit R2.

The elliptic orbits R1 and R2 of the projection 31a generated by the above-described vibration of the actuator 30 make contact with the driven body 20 by being biased by the biasing force, and drive the driven body 20 in the directions of arrows r1 and r2 shown in the drawings. In the motor 100 which is driven in this manner, to secure the driven body 20 to the base 10 in such a way that the driven body 20 can rotate, a predetermined clearance or the like is created between the unillustrated bearing and the rotating shaft 21. Moreover, the support 40 which is slidably secured to the base 10 is also secured to the base 10 in such a way that the support 40 can slide on the base 10 by an appropriate clearance created between a mounting section for the support 40, the mounting section formed of the rail 10a provided on the base 10 and the fixing pin 70, and the support 40. This induces deflection or backlash behaviors of the driven body 20 and the actuator 30 secured to the support 40.

Even when there are factors inducing the deflection or backlash in the driven body 20 and the actuator 30, by mounting the coil spring 60 which is the biasing unit in the motor 100 at an angle θ as shown in FIG. 2B, it is possible to prevent deflection or backlash which may occur when the driven body 20 is being driven.

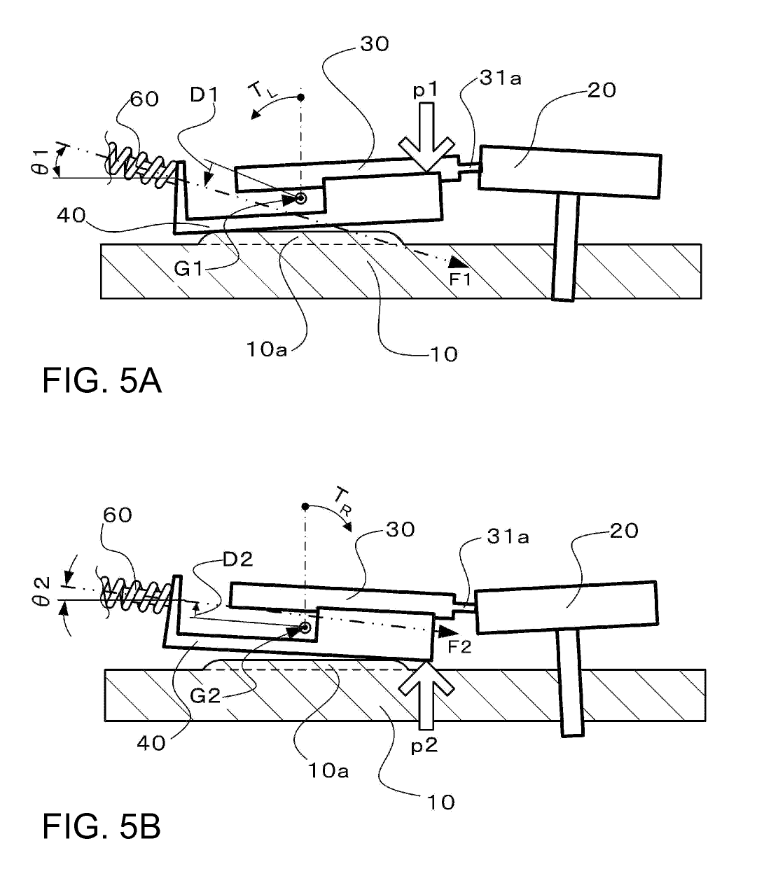

FIGS. 5A and 5B are schematic diagrams illustrating how to prevent deflection and backlash by the coil spring 60. FIG. 5A shows a case in which the direction of a biasing force F1 generated by the coil spring 60 mounted at an angle θ1 is away from a barycenter G1 by D1 to the side where the base 10 is located, the barycenter G1 in a state in which the actuator 30 is secured to the support 40. At this time, moment of “F1×D1” acts on the support 40 by the biasing force F1 and rotates the support 40 in the direction of T_{L} shown in the drawing. As a result, the projection 31a is pushed upward in the drawing, and a portion of the driven body 20 with which the projection 31a comes into contact, the portion with which the projection 31a makes contact, is also pushed upward in the drawing.

In this state, since the biasing force F1 is made to act at all times by the coil spring 60, the driven body 20 is driven in a state in which the projection 31a and the portion of the driven body 20 with which the projection 31a makes contact are always pushed upward in the drawing. In other words, in this state, the driven body 20 is driven with the state shown in FIG. 5A being stably maintained. Therefore, even when the deflection or backlash occurs due to the clearance between the support 40 and the base 10 and the clearance between the driven body 20 and the base 10 as described earlier, by mounting the coil spring 60 as the biasing unit at an angle θ1, it is possible to obtain the motor 100 that drives the actuator 30 and the driven body 20 while always biasing the actuator 30 and the driven body 20 in the same direction.

FIG. 5B shows a case in which, unlike FIG. 5A, the direction of a biasing force F2 generated by the coil spring 60 mounted at an angle θ2 is away from a barycenter G2 by D2 in the direction opposite to the side where the base 10 is located, the barycenter G2 in a state in which the actuator 30 is secured to the support 40. Therefore, moment of “F2×D2” rotates the support 40 in the direction of T_{R} shown in the drawing, the projection 31a is pushed downward in the drawing, and a portion of the driven body 20 with which the projection 31a comes into contact, the portion with which the projection 31a makes contact, is also pushed downward in the drawing. As a result, by mounting the coil spring 60 at an angle θ2, it is possible to obtain the motor 100 that drives the actuator 30 and the driven body 20 while always biasing the actuator 30 and the driven body 20 in the same direction.

To prevent the projection 31a of the actuator 30 from being pushed upward excessively in the state shown in FIG. 5A, the springs 80 regulating the front sides 40f of the fixing sections 40a of the support 40 shown in FIG. 3A regulate the projection 31a in a direction p1 shown in FIG. 5A. Moreover, to prevent the projection 31a of the actuator 30 from being pushed downward excessively in the state shown in FIG. 5B, the springs 81 regulating the back sides 40g of the support 40 shown in FIG. 3B regulate the projection 31a in a direction p2 shown in FIG. 5B.

As described above, in the motor 100 according to this embodiment, even when a predetermined clearance is created between the driven body 20 which is a movable element and the base 10 and between the support 40 which is a movable element and the base 10 to move the driven body 20 and the support 40 with respect to the base 10 and this clearance causes deflection or backlash, by always biasing the driven body 20 and the support 40 in a given direction by mounting the coil spring 60 as the biasing unit in such a way as to form a predetermined angle θ with respect to the direction in which the actuator 30 is biased, it is possible to prevent a slip in a region of contact between the projection 31a of the actuator 30 and the driven body 20, the region of contact that is irrelevant to the driving, and convert the vibration of the actuator 30 efficiently into the driving force to drive the driven body 20.

### Second Embodiment

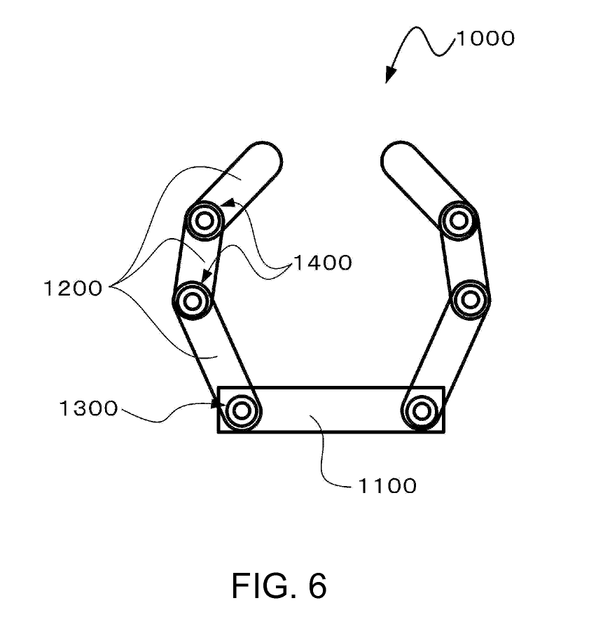

FIG. 6 is an appearance diagram showing a robot hand 1000 according to a second embodiment, the robot hand 1000 provided with the motor 100. The robot hand 1000 includes a base portion 1100 and finger sections 1200 connected to the base portion 1100. The motor 100 is incorporated into connections 1300 between the base portion 1100 and the finger sections 1200 and joint sections 1400 between the finger sections 1200. When the motor 100 is driven, the finger sections 1200 bend and can grip an object. By using the motor 100 which is an ultrasmall motor, it is possible to implement a robot hand which is compact but is provided with a large number of motors.

### Third Embodiment

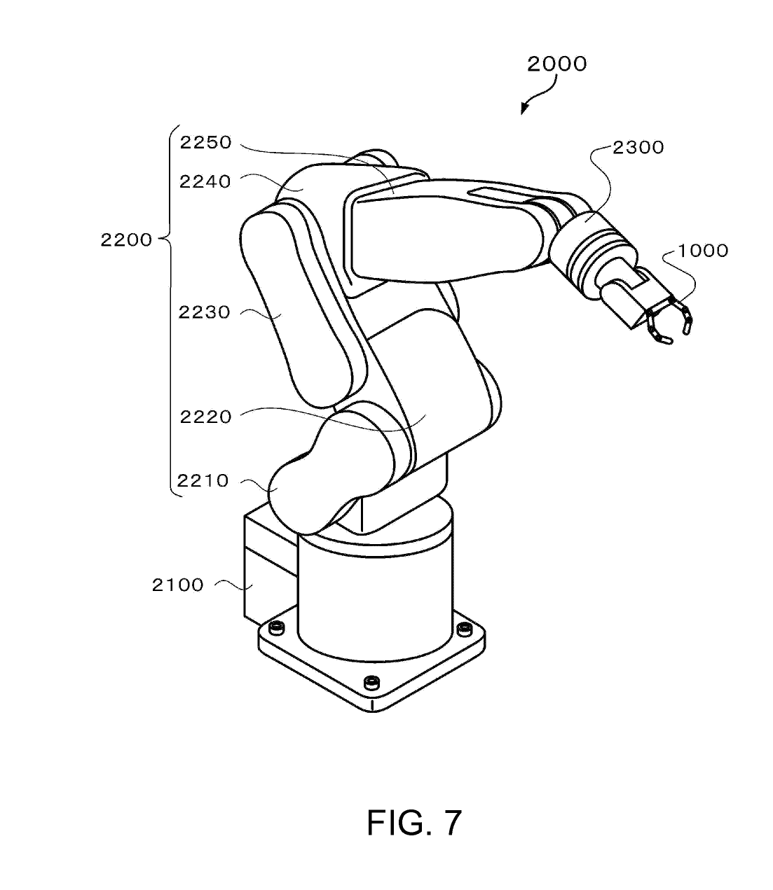

FIG. 7 is a diagram showing the structure of a robot 2000 provided with the robot hand 1000. The robot 2000 is formed of a main body section 2100, an arm section 2200, the robot hand 1000, etc. The main body section 2100 is secured to, for example, a floor, a wall, a ceiling, and a movable carriage. The arm section 2200 is movably provided on the main body section 2100, and an unillustrated actuator that generates power to rotate the arm section 2200, a control unit controlling the actuator, and the like are built into the main body section 2100.

The arm section 2200 is formed of a first frame 2210, a second frame 2220, a third frame 2230, a fourth frame 2240, and a fifth frame 2250. The first frame 2210 is connected to the main body section 2100 by a rotating and bending shaft in such a way as to be able to rotate or bend. The second frame 2220 is connected to the first frame 2210 and the third frame 2230 by rotating and bending shafts. The third frame 2230 is connected to the second frame 2220 and the fourth frame 2240 by rotating and bending shafts. The fourth frame 2240 is connected to the third frame 2230 and the fifth frame 2250 by rotating and bending shafts. The fifth frame 2250 is connected to the fourth frame 2240 by a rotating and bending shaft. The arm section 2200 is controlled by the control unit so that the frames 2210 to 2250 move in a coordinated fashion while rotating or bending about the rotating and bending shafts.

To an end of the fifth frame 2250 of the arm section 2200, the end opposite to the end to which the fourth frame 2240 is connected, a robot hand connection 2300 is connected, and the robot hand 1000 is attached to the robot hand connection 2300. The motor 100 that rotates the robot hand 1000 is built into the robot hand connection 2300, and the robot hand 1000 can grip an object. By using the compact and lightweight robot hand 1000, it is possible to provide a robot that is highly versatile and can perform assembly, inspections, etc. of a sophisticated electronic apparatus.

The entire disclosure of Japanese Patent Application No. 2011-102756, filed May 2, 2011 is expressly incorporated by reference herein.

What is claimed is:

1. A motor comprising:
a driven unit;
an actuator including a vibrating plate having, at an end thereof, a protrusion which is biased toward the driven unit and a piezoelectric body stacked on the vibrating plate; and
a biasing unit biasing the actuator toward the driven unit,
wherein
an axis in a direction in which the biasing unit biases the actuator toward the driven unit intersects with a plane containing a vibrating surface of the vibrating plate.

2. The motor according to claim 1, wherein
an angle θ at which the axis in the direction in which the biasing unit biases the actuator toward the driven unit intersects with the plane containing the vibrating surface satisfies 0<θ≦30°.

3. The motor according to claim 1, further comprising:
a regulating unit regulating the actuator in a direction intersecting with the plane containing the vibrating surface.

4. A robot hand comprising the motor according to claim 1.

5. A robot comprising the robot hand according to claim 4.

6. A robot hand comprising:
a driven unit;
an actuator including a piezoelectric body having a protrusion which is biased toward the driven unit;
a biasing unit biasing the actuator toward the driven unit; and
a gripping section gripping an object,
wherein
an axis in a direction in which the biasing unit biases the actuator toward the driven unit intersects with a plane containing a vibrating surface of the piezoelectric body.

7. The robot hand according to claim 6, wherein
an angle θ at which the axis in the direction in which the biasing unit biases the actuator toward the driven unit intersects with the plane containing the vibrating surface satisfies 0<θ≦30°.

8. A robot comprising:
a driven unit;
an actuator including a piezoelectric body having a protrusion which is biased toward the driven unit;
a biasing unit biasing the actuator toward the driven unit; and
a rotatable arm section,
wherein
an axis in a direction in which the biasing unit biases the actuator toward the driven unit intersects with a plane containing a vibrating surface of the piezoelectric body.

9. The robot according to claim 8, wherein
an angle θ at which the axis in the direction in which the biasing unit biases the actuator toward the driven unit intersects with the plane containing the vibrating surface satisfies 0<θ≦30°.
